(19) United States
(12) Patent Application Publication
(10) Pub. No.: US 2002/0048953 A1
(43) Pub. Date: Apr. 25, 2002

(54) Chemical mixture for copper removal in electroplating systems

(76) Inventor: Radha Nayak, Santa Clara, CA (US)

Correspondence Address: PATENT COUNSEL, APPLIED MATERIALS, INC., Legal Affairs Department, P.O. BOX 450A, Santa Clara, CA, 95052, US

(21) Appl. No.: 09/883,074

(22) Filed: Jun. 15, 2001

Related U.S. Application Data
(60) Provisional application No. 60/212,059, filed on Jun. 16, 2000.

(51) Int. Cl. H01L 21/302; H01L 21/461

(52) U.S. Cl. 438/689

(57) ABSTRACT

A method and chemical composition for selectively etching unwanted metal deposits on a surface of a wafer. In one aspect, a method of processing a substrate is provided which includes providing a substrate to an edge bead removal system, and applying a chemical etchant comprising citric acid and an oxidizing agent to the substrate. In one aspect, a chemical composition of citric acid and hydrogen peroxide is provided which is a relatively weak acid having a pH greater than about 1.0.

### BACKGROUND OF THE INVENTION

This application claims benefit of U.S. provisional patent application Ser. No 60/212,059, filed Jun. 16, 2000, which is herein incorporated by reference.

### FIELD OF THE INVENTION

The present invention relates to electro-chemical deposition or electroplating processes. More particularly, the invention relates to a chemical composition to remove copper deposits resulting from electro-chemical deposition or electroplating processes.

### BACKGROUND OF THE RELATED ART

In the fabrication of integrated circuits and other electronic devices, multiple layers of conducting, semiconducting, and dielectric materials are deposited on or removed from a surface of a substrate. Thin films of conducting, semiconducting, and dielectric materials may be deposited by a number of deposition techniques. Common deposition techniques in modern processing include physical vapor deposition (PVD), also known as sputtering, chemical vapor deposition (CVD), plasma-enhanced chemical vapor deposition (PECVD), and now electro-chemical plating (ECP) deposition.

Metal electro-chemcial plating is being used to deposit elemental metals or metal alloys, including copper, on vias and contacts on semiconductor devices. The electro-chemical plating process is a wet process in which the substrate is partially or completely immersed in an electrolyte solution comprising free metal ions. Copper is becoming a metal of choice for integrated circuits and other electronic devices due to its low electrical resistivity and high resistance to electromigration, which are important characteristics for supporting the higher current densities experienced at high levels of integration and increased device speed. Copper also possesses excellent thermal conductivity and is readily available in a highly pure state.

One disadvantage to a wet process, such as the electro-chemcial plating deposition process, is that unwanted metal deposits may form on undesired surfaces of the substrate such as the sides and the backside of the substrate. For example, FIG. 1 shows a cross-sectional view of an edge of a substrate 22 having a layer formed thereon by ECP. The substrate 22 includes bevel edges 33, a seed layer 34, and an electroplated conductive metallic layer 38 deposited on the seed layer 34 by the ECP process. Commonly, the metallic layer 38 is substantially thicker at the edge of the substrate 22 and forms what is known as an edge bead 36. The edge bead 36 is most likely caused by higher current densities at the edge of the substrate 22 and usually forms within 2-5 mm of the bevel edge 33.

In addition to thickness irregularity, the edge bead 36 is often deposited directly on the surface of the substrate 22 or outside the coverage area of the seed layer 34. A metal layer deposited directly on the surface of the substrate exhibits poor adhesion to the substrate. Consequently, downstream processes such as chemical-mechanical planarization (CMP), for example, may cause the metal deposit to flake, or otherwise peal away from the substrate 22. Therefore, it is desirable to remove the edge bead 36 from the substrate to prevent flaking and to ensure thickness uniformity across the conductive metallic layer deposited on the substrate 22.

Furthermore, copper may deposit on the backside of the substrate 22 during the electroplating process causing contamination of the substrate 22. Copper contamination results in the degradation of wafer performance and may occur when copper forms on the backside of the substrate and diffuses through a silicon layer and into the electronic device. Copper contamination may also occur when a seed layer 34 wraps around to the backside of the substrate to which copper is deposited. Copper contamination may further occur when the electrolyte solution of the ECP process dries on the backside of the substrate.

Edge bead removal (EBR) systems have been used to remove these undesired metal deposits on a substrate surface, including the backside of the substrate. EBR systems apply chemical etchants to the substrate surface to selectively etch undesired metal deposits. Chemical etchants may consist of highly acidic compositions such as nitric acid, sulfuric acid, and ferric chloride or alkaline-based compositions such as ammonium bicarbonate.

However, highly acidic or caustic etchants are not sufficiently selective for materials desired to be etched. These etchants also adversely affect surrounding equipment due to their corrosive acidic or alkaline nature and thus, are difficult to transport, handle, store, and discard. These etchants are even more detrimental at elevated temperatures which are required to achieve increased etch rates since highly acidic and highly caustic etchants volatize at higher temperatures. The volatilization of highly acidic and highly caustic etchants potentially introduces toxic gas to the surrounding environment.

Therefore, there exists a need for a chemical etchant that can effectively remove unwanted metal deposits from a surface of a substrate.

### SUMMARY OF THE INVENTION

The present invention generally provides an etching solution and method for copper removal from a surface of a substrate. In one aspect, the chemical etchant includes about 0.5% by weight to about 10% by weight of citric acid mixed with about 1% by weight to about 10% by weight of hydrogen peroxide. In another aspect, the etchant composition includes about 4.5% by weight to about 8% by weight of citric acid and about 3% by weight to about 5% by weight of hydrogen peroxide. In still another aspect, the etchant composition includes about 8% by weight of citric acid and about 5% by weight of hydrogen peroxide.

One embodiment of a method for processing substrates includes providing a substrate to an edge bead removal system, and applying a chemical etchant comprising citric acid and an oxidizing agent to the substrate. In one aspect, the chemical etchant is applied having a temperature of about 20° C. to about 60° C.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a cross-sectional view of an electroplated substrate.

FIG. 2 is a schematic perspective view of an edge bead removal system.

FIG. 3 is a graphical representation of the etch removal rate relative to temperature by a chemical etchant composition of the present invention.

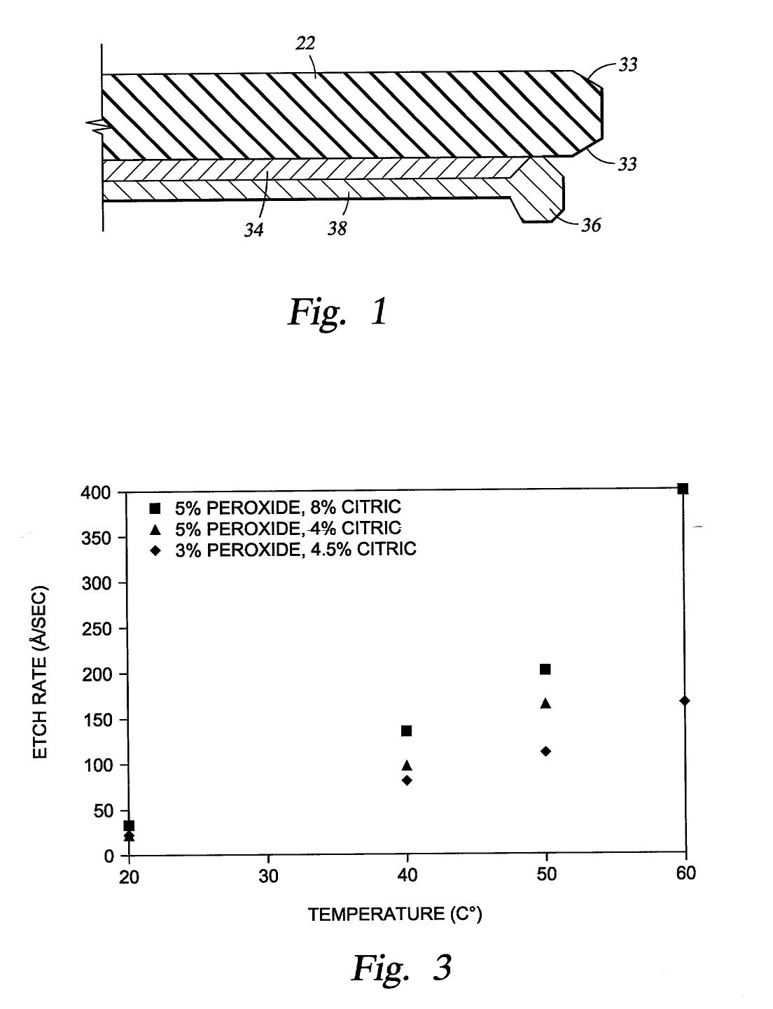

### DETAILED DESCRIPTION OF THE INVENTION

The present invention provides an etching solution and method to selectively remove unwanted copper deposits from a surface of a substrate. The etching solution includes an aqueous solution of citric acid and an oxidizing agent. In one aspect, the oxidizing agent is hydrogen peroxide. The etching solution is a relatively weak acid having a pH of greater than about 1.0, which includes about 0.5% by weight to about 10% by weight of citric acid mixed with about 1% by weight to about 10% by weight of hydrogen peroxide. In one aspect, the etching solution includes about 4.5% by weight to about 8% by weight of citric acid and about 3% by weight to about 5% by weight of hydrogen peroxide. In another aspect, the etching solution includes about 8% by weight of citric acid and about 5% by weight of hydrogen peroxide.

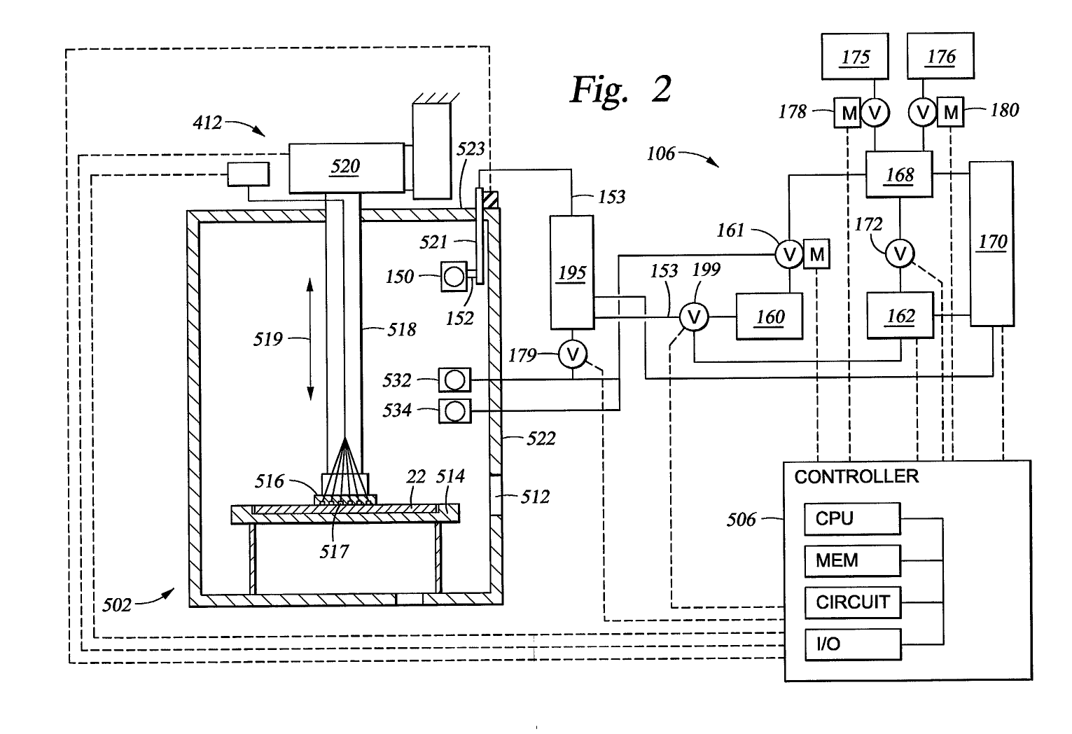

The etching solution is typically applied to a substrate using an edge bead removal (EBR) module in conjunction with or separate from a spin-rinse-dry (SRD) system. The etching solution may be applied to a substrate at a temperature ranging from about 20° C. and about 60° C. In one embodiment, the etching solution is applied to a substrate at about 55° C. The etchant may also be used in conjunction with other copper removal systems. For ease and clarity of description, the invention will be described as it relates to an EBR module as shown in FIG. 2.

FIG. 2 is a schematic perspective view of an EBR module 412. One embodiment that can be used to advantage is disclosed in Provisional U.S. patent application Ser. No. 60/191,387, entitled “Method and Apparatus for Removal of Unwanted Electroplating Deposits” filed on Mar. 22, 2000, which is incorporated herein by reference. A general description thereof is set forth below.

The EBR module 412 includes a chamber 502, an etchant/chemical delivery assembly 106, and a controller 506. The chamber 502 includes a chamber side wall 522 having a slit valve 512 through which a substrate 22 may be inserted and removed. The substrate 22 is transferred to and from the chamber 502 through the slit valve 512 by means of, for example, a robot arm (not shown) of a type known in the art. The robot arm or other transfer member deposits the substrate 22 on a platform 514 within the EBR chamber 502.

The chamber 502 also includes a vacuum chuck 516 connected to or otherwise mounted on a spindle shaft 518. The vacuum chuck 516 is generally cylindrical in shape and includes a lower surface having grooves 517 formed therein. The vacuum chuck 516 is connected to a vacuum source (not shown) by a conduit (also not shown) disposed within the spindle shaft 518. The vacuum source supplies a negative pressure through the vacuum chuck 516 that is sufficient to engage the substrate 22 and hold the substrate on the lower surface of the vacuum chuck 516. The spindle shaft 518 may be supported by a rotary actuator 520, which is vertically movable in the chamber. The vertical movement of the spindle shaft 518 is represented by arrows 519. The actuator 520 is capable of rotating the spindle at a desired angular velocity of, for example, about 2000 RPM.

The EBR chamber 502 further includes one or more nozzles 150 disposed on or otherwise connected to one or more dispenser arms 152 for dispensing the chemical etchant. The dispenser arm 152 is structurally and fluidly coupled to a post 521 that passes through a chamber ceiling 523. The post 521 can be rotated by an actuator (not shown) in a manner that extends or retracts the dispenser arm 152 relative to the chamber sidewall 522. When the dispenser arm 152 is extended, the nozzle 150 is positioned underneath and in close proximity to the substrate 22. The nozzle 150 is also adjustable so that the nozzle 150 can direct fluid at substrates of various diameters. Although not shown, any number of nozzles 150 may be disposed at substantially equally spaced intervals about the interior of the chamber 502.

The EBR chamber 502 is also equipped with rinse nozzles 532 and 534 which extend through the chamber sidewall 522. Rinse nozzles 532 and 534 are each in fluid communication with a fluid source 160, such as a de-ionized water source, via valve 161. The rinse nozzles 532 and 534 are each positioned to dispense the fluid over an adjacent surface of the substrate 22. Though one valve 161 is shown as controlling the rinse fluid flow to all rinse nozzles 532 and 534, each rinse nozzle may have a distinct valve to permit independent operation.

The etchant/chemical delivery assembly 106 provides online metering, mixing, and dilution of the etchant or other cleaning chemicals. The etchant/chemical delivery assembly 106 includes a make-up tank 168, an etchant tank 162, a heating tank 195, a plurality of valves 172, 179, 199, a plurality of metering valves 161, 178, 180, a pressure source 170, a de-ionized water source 160, an acid supply 175, and an oxidizer supply 176.

The pressure source 170 may include a pressurized inert gas such as nitrogen, a hydraulic pump, and any other systems capable of transferring fluid. The pressure source 170 transfers the chemical components between the make-up tank 168, the etchant tank 162, the heating tank 195, and the nozzle 150. The pressure source 170 may also transfer de-ionized water from the de-ionized water supply 160 to the rinse nozzles 532 and 534.

Metering valves 161, 178, and 180 control and regulate the flow of de-ionized water, acid, and oxidizing agent, respectively, to the make-up tank 168 where the chemicals are mixed by means of agitation, diffusion, or any other method of mixing. The chemical etchant may be prepared in a batch or continuous operation depending on production requirements.

The etchant tank 162 serves as a reservoir to store the mixed etchant in a form that is ready for application. The heating tank 195 is provided with heating elements (not shown) to heat the contents thereof to a desired processing temperature. The heating tank 195 is provided in close proximity, typically three feet or less, to the nozzles 150 to minimize the temperature loss of the etchant prior to being applied to the substrate.

The controller 506 controls the overall operation of the chemical/etchant delivery assembly 106 including the flow rates of the etchant components, the operating pressure of the system, the sequencing of the valves, and the spin cycle(s) of the substrates. Thus, the controller 506 allows an operator to produce a specific etchant composition comprising de-ionized water from the de-ionized water source 160, acid from the acid supply 175, and oxidizing agent from the oxidizer supply 176. The controller may be remotely located in a control panel or control room and controlled with remote actuators. The controller 506 may be fashioned as a microcontroller, a microprocessor, a general-purpose computer, or any other known applicable type of computer. The application integration of programmable controllers is well known and will not be further detailed herein.

In operation, a substrate 22 is inserted through the slot 512 onto the platform 514 by a robot device (not shown). The substrate is positioned process side down on the platform 514. The actuator 520 displaces the spindle shaft 518 and vacuum chuck 516 downwardly until the lower surface of the vacuum chuck 516 contacts the substrate 22. The vacuum source (not shown) is then actuated so that the negative pressure holds the substrate 22 to the lower surface of the vacuum chuck 516.

The mixed etchant from the etchant mix tank 168 flows by gravity or is pumped by the pressure source 170 to the etchant tank 162. From the etchant tank 162, etchant flows by gravity or is pumped by the pressure source 170 via a conduit 153 through the heating tank 195 and through the nozzles 150 to the substrate 22. The heating tank 195 typically heats the etchant between about 25° C. and about 65° C.

The actuator 520 rotates the spindle shaft 518, the vacuum chuck 516, and the substrate 22 at approximately 200 RPM as the chemical etchant is sprayed through the nozzle 150 to the surface of the substrate. The substrate 22 is typically rotated to provide substantially equal exposure to the etchant at the peripheral portion of the substrate 22. The substrate 22 is usually rotated in the same direction as the direction of the etchant spray pattern to facilitate controlled edge bead removal adjacent the bevel edge of the substrate 22. The substrate 22 may be rotated at an angular velocity between about 100 rpm and about 1,000 rpm. In one embodiment, the substrate 22 is rotated between about 500 rpm and about 1,000 rpm.

Following the etching process, the substrate typically undergoes a spin-rinse dry process (SRD). The SRD process, in general, delivers de-ionized water to the upper and lower surfaces of the substrate 22 through the rinse nozzles 523 and 534 to rinse residual etchant and other chemicals from the substrate 22 while the substrate spins at a speed sufficient to dry the substrate. Once dried, the substrate 22 is transferred from the chamber 502, and is ready for subsequent processing.

The following example is provided to further illustrate the invention.

### EXAMPLE 1

A chemical etchant composition of 5% by weight of hydrogen peroxide and 8% by weight of citric acid was prepared. The composition was heated to between about 20° C. to about 60° C. and dispensed onto the edge of a wafer using a disposable pipette held stationary at a distance of two millimeters above a wafer rotated at 70 rpm.

FIG. 3 summarizes the etch rate of the composition as a function of temperature. As shown in FIG. 3, a weak acidic etchant comprising 8% by weight of citric acid and 5% by weight of hydrogen peroxide achieved an etch removal rate of 400 angstroms per second. This etch rate is equivalent to etching a film of copper approximately 1 μm thick in 15 seconds.

While foregoing is directed to the preferred embodiment of the present invention, other and further embodiments of the invention may be devised without departing from the basic scope thereof is determined by the claims that follow.

What is claimed is:

1. An etching solution comprising citric acid and an oxidizing agent.

2. The etching solution of claim 1, wherein the oxidizing agent is hydrogen peroxide.

3. The etching solution of claim 1, wherein the solution has a pH of greater than about 1.0.

4. The etching solution of claim 1, wherein the solution has a pH of about 1.5.

5. The etching solution of claim 1, wherein the solution comprises about 0.5% to about 10% by weight citric acid and about 1% to about 10% by weight hydrogen peroxide.

6. The etching solution of claim 1, wherein the solution comprises about 4.5% to about 8% by weight citric acid and about 3% to about 5% by weight hydrogen peroxide.

7. The etching solution of claim 1, wherein the solution comprises about 8% by weight citric acid and about 5% by weight hydrogen peroxide.

8. An etching solution, comprising citric acid and hydrogen peroxide.

9. The etching solution of claim 8, wherein the solution has a pH of greater than about 1.0.

10. The etching solution of claim 8, wherein the solution has a pH of about 1.5.

11. The etching solution of claim 8, wherein the solution comprises about 4.5% to about 8% by weight citric acid and about 3% to about 5% by weight hydrogen peroxide.

12. The etching solution of claim 8, wherein the solution comprises about 8% by weight citric acid and about 5% by weight hydrogen peroxide.

13. A method of processing a substrate, comprising:
providing a substrate to an edge bead removal system; and
applying a chemical etchant comprising citric acid and an oxidizing agent to the substrate.

14. The method of claim 13, further comprising rinsing the substrate with water.

15. The method of claim 14, further comprising spin-drying the substrate.

16. The method of claim 13, wherein the oxidizing agent is hydrogen peroxide.

17. The method of claim 13, wherein the chemical etchant has a pH of greater than about 1.0.

18. The method of claim 13, wherein the chemical etchant has a pH of about 1.5.

19. The method of claim 13, wherein the chemical etchant has a temperature of about 20° C. to about 60° C.

20. The method of claim 13, wherein the chemical etchant has a temperature of 55° C.

21. The method of claim 13, wherein the chemical etchant comprises about 0.5% to about 10% by weight citric acid and about 1% to about 10% by weight hydrogen peroxide.

22. The method of claim 13, wherein the chemical etchant comprises about 4.5% to about 8% by weight citric acid and about 3% to about5% by weight hydrogen peroxide.

23. The method of claim 13, wherein the chemical etchant comprises about 8% by weight citric acid and about 5% by weight hydrogen peroxide.
